(19) United States
(12) Patent Application Publication
(10) Pub. No.: US 2026/0190276 A1
(43) Pub. Date: Jul. 2, 2026

(54) Server Information Handling System Power Division and Identification System

(71) Applicant: Dell Products L.P., Round Rock, TX (US)

(72) Inventors: Jason Pritchard, Hopkinton, MA (US); Charles Ziegler, East Providence, RI (US); Andrew Barada, Newton, MA (US)

(21) Appl. No.: 19/008,425

(22) Filed: Jan. 2, 2025

(51) Int. Cl. H05K 7/14; G06F 1/26

(52) U.S. Cl. CPC H05K 7/1492; G06F 1/26; H05K 7/1498

(57) ABSTRACT

A power division and identification environment for an information handling system. The power division and identification environment includes a plurality of components; and, a power system providing power to the plurality of components, the power system including a power division and identification system, the power division and identification system comprising a power division and identification control circuit; a first power division and identification component circuit, the power division and identification circuit and the first power division and identification component circuit being coupled via a first monitored and controlled ground signal path and a common passive ground signal path; and, a second power division and identification component circuit, the power division and identification circuit, the power division and identification circuit and the second power division and identification component circuit being coupled via a second monitored and controlled ground signal path and the common passive ground signal path.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with power division and identification system.

In one embodiment, the invention relates to a power division and identification system for use with an information handling system, comprising: a power division and identification control circuit; a first power division and identification component circuit, the power division and identification circuit and the first power division and identification component circuit being coupled via a first monitored and controlled ground signal path and a common passive ground signal path; and, a second power division and identification component circuit, the power division and identification circuit, the power division and identification circuit and the second power division and identification component circuit being coupled via a second monitored and controlled ground signal path and the common passive ground signal path.

In another embodiment, the invention relates to a power division and identification environment for an information handling system comprising a plurality of components; and, a power system providing power to the plurality of components, the power system including a power division and identification system, the power division and identification system comprising a power division and identification control circuit; a first power division and identification component circuit, the power division and identification circuit and the first power division and identification component circuit being coupled via a first monitored and controlled ground signal path and a common passive ground signal path; and, a second power division and identification component circuit, the power division and identification circuit, the power division and identification circuit and the second power division and identification component circuit being coupled via a second monitored and controlled ground signal path and the common passive ground signal path.

In another embodiment, the invention relates to a system comprising: a chassis; a plurality of components contained within the chassis; and, a power system providing power to the plurality of components, the power system including a power division and identification system, the power division and identification system comprising a power division and identification control circuit; a first power division and identification component circuit, the power division and identification circuit and the first power division and identification component circuit being coupled via a first monitored and controlled ground signal path and a common passive ground signal path; and, a second power division and identification component circuit, the power division and identification circuit, the power division and identification circuit and the second power division and identification component circuit being coupled via a second monitored and controlled ground signal path and the common passive ground signal path.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a generalized schematic view of a power division and identification system.

FIG. 5 shows a generalized schematic view of a power division and identification system.

### DETAILED DESCRIPTION

Various aspects of the present disclosure include an appreciation that server type information handling system structural designs are becoming increasingly large as a function of growing component size and increasing heat loads within the system. Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) and drive modules are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system.

Various aspects of the present disclosure include an appreciation that GPU modules are often configured to conform to form factor standards. Various aspects of the present disclosure include an appreciation that the card electromechanical (CEM) form factor standard is one such form factor standard. Various aspects of the disclosure include an appreciation that it is known to provide information handling systems with baseboard systems such as peripheral component interconnect express (PCIe) type baseboard systems.

Various aspects of the present disclosure include an appreciation that power connections used to power components often require individual respective power cables. Various aspects of the present disclosure include an appreciation that with many known information handling system designs each of the plurality of components within the information handling system are coupled to power via a respective system side power connector.

Various aspects of the present disclosure include an appreciation that these power connections can present one or more issues associated with an information handling system design. For example, these power connections often occupy valuable space within the information handling system, often add cost to the information handling system and often add assembly time to the fabrication of the information handling system. These issues are especially present in systems which are designed with a plurality of components such as a plurality of GPUs or a plurality of drives. These issues are also especially present in systems which are designed with an array of AICs, such as in systems which are designed to support artificial intelligence (AI) workloads.

Various aspects of the present disclosure include an appreciation that information handling system power systems are often configured to conform to standards. Various aspects of the present disclosure include an appreciation that the peripheral component interconnect service identifier card electromechanical (PCI-SID-CEM) standard is one such power system standard. Various aspects of the present disclosure include an appreciation that certain power system standards, such as the PCI-SID-CEM standard, do not include cable detection functionality. For example, PCI-SIG CEM 2×4 and 2×3 AUX PWR connectors do not include cable connect detection functionality so there is no way of knowing whether a power cable is connected to an intended card. Typically, in other cable/connector interfaces, such as the 12V-2×6 cable/connector interface, additional sideband pins are used to provide cable connection detection functionality.

Various aspects of the present disclosure include an appreciation that it would be desirable to provide a power detection solution which does not require any additional sideband pins. Various aspects of the present disclosure include an appreciation that it would be desirable to provide a power detection solution which uses ground pins such as ground pins which are already available across a component power interface.

A system and method are disclosed for providing a server type information handling system with a power division and identification system. In certain embodiments, the power division and identification system include a power division and identification control circuit, a first power division and identification component circuit, a second power division and identification component circuit, or a combination thereof. In certain embodiments, the power division and identification control circuit is associated with a power system of the server type information handling system. In certain embodiments, the first power division and identification control circuit is associated with a power system of a first component of the information handling system. In certain embodiments, the second power division and identification control circuit is associated with a power system of a second component of the information handling system.

In certain embodiments, the power division and identification circuit, the first power division and identification component circuit and second power division and identification component circuit are coupled via respective monitored and controlled ground signal paths, a common power and sideband signal path, a common passive ground signal path, or a combination thereof. In certain embodiments, the respective monitored and controlled ground signal paths, the common power and sideband signal path, the common passive ground signal path, or a combination thereof, are connected to the power division and identification circuit via a power system power connector. In certain embodiments, the respective monitored and controlled ground signal paths, the common power and sideband signal path, the common passive ground signal path, or a combination thereof, are connected to the first power division and identification component circuit and the second power division and identification component circuit via a first component power system power connector and a second component power system power connector.

In certain embodiments, the first power division and identification component circuit is associated with a first AIC or drive power connector and the second power division and identification component circuit is associated with a second AIC or drive power connector. Accordingly in certain embodiments, a single power connector is split to multiple separate AIC power connectors. Therefore, to power 8x double wide cards or 16x single wide cards in the same chassis, only 8x source power connectors are needed, assuming the power source connector is adequately gauged to support the periphery loads. In certain embodiments, to enable cable assertion detection between the single power source and the multiple periphery loads (granularly down to a per peripheral basis), grounds are monitored by a power division and identification circuit control device. In certain embodiments, the power division and identification system uses per component monitored/controlled ground signal paths that, when combined with a passive ground on the component side, the cable-to-periphery AIC connection can be identified as ‘asserted’ when the cable is coupled to the respective component by coupling the monitored ground to the passive ground.

Accordingly, a power division and identification system is disclosed which provides a power detection solution which does not require any additional sideband signal paths. Such a power division and identification system provides a power detection solution a power detection solution which uses ground pins such as ground pins which are already available across a component power interface. Such a power division and identification system provides a method to determine cable/connector assertion between a power source connector and a plurality of different component loads on a per component basis by using ground signal paths.

Such a power division and identification system advantageously can be used in a plurality of applications (e.g., theoretically wherever there are cables/connectors that have grounds across the interface and those grounds are tied together at the peripherals). Such a power division and identification system advantageously removes the need for discrete signals for connector/cable assertion detection to validate cable/connectors. Such a power division and identification system advantageously allows for a plurality of components to be powered from a single power source while still achieving cable/connector assertion detection on a per component basis without requiring additional signals.

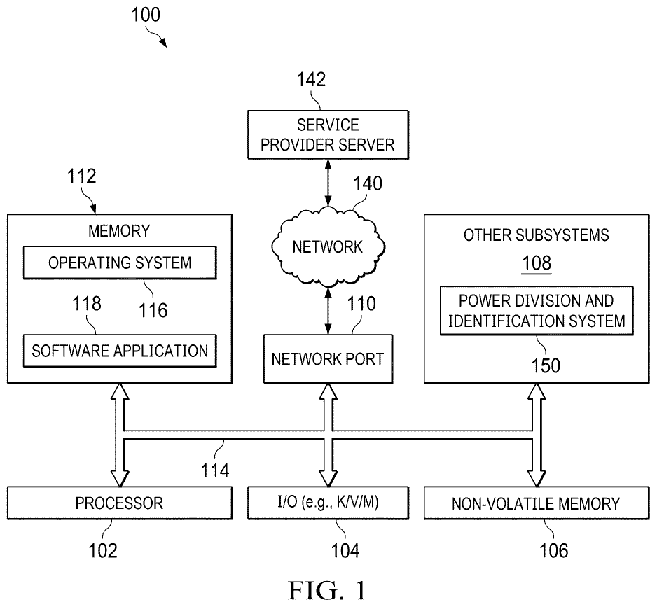

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a power division and identification system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the power division and identification system 150 is part of a power division and identification environment which includes a includes a power system and a plurality of components coupled to the power system. In certain embodiments, the plurality of components are arranged as an array of components. In certain embodiments, the plurality of components includes a plurality of GPUs, a plurality of drives, or a combination thereof. In certain embodiments, the plurality of GPUs, the plurality of drives, or a combination thereof, are designed to support artificial intelligence (AI) workloads.

In certain embodiments, the power division and identification system 150 includes a power division and identification control circuit, a first power division and identification component circuit, a second power division and identification component circuit, or a combination thereof. In certain embodiments, the power division and identification control circuit is associated with a power system of the server type information handling system. In certain embodiments, the first power division and identification control circuit is associated with a power system of a first component of the information handling system. In certain embodiments, the second power division and identification control circuit is associated with a power system of a second component of the information handling system.

In certain embodiments, the power division and identification circuit, the first power division and identification component circuit and second power division and identification component circuit are coupled via respective monitored and controlled ground signal paths, a common power and sideband signal path, a common passive ground signal path, or a combination thereof. In certain embodiments, the respective monitored and controlled ground signal paths, the common power and sideband signal path, the common passive ground signal path, or a combination thereof, are connected to the power division and identification circuit via a power system power connector. In certain embodiments, the respective monitored and controlled ground signal paths, the common power and sideband signal path, the common passive ground signal path, or a combination thereof, are connected to the first power division and identification component circuit and the second power division and identification component circuit via a first component power system power connector and a second component power system power connector.

In certain embodiments, the first power division and identification component circuit is associated with a first AIC power connector and the second power division and identification component circuit is associated with a second AIC power connector. Accordingly in certain embodiments, a single power connector is split to multiple separate AIC power connectors. Therefore, to power 8x DW cards or 16x SW cards in the same chassis, only 8x source power connectors are needed, assuming the power source connector is adequately gauged to support the periphery loads. In certain embodiments, to enable cable assertion detection between the single power source and the multiple periphery loads (granularly down to a per peripheral basis), grounds are monitored by a power division and identification circuit control device. In certain embodiments, the power division and identification system uses per component monitored/controlled ground signal paths that, when combined with a passive ground on the component side, the cable-to-periphery AIC connection can be identified as ‘asserted’ when the cable is coupled to the respective component by coupling the monitored ground to the passive ground.

Accordingly, a power division and identification system is disclosed which provides a power detection solution which does not require any additional sideband signal paths. Such a power division and identification system provides a power detection solution which uses ground pins such as ground pins which are already available across a component power interface. Such a power division and identification system provides a method to determine cable/connector assertion between a power source connector and a plurality of different component loads on a per component basis by using ground signal paths.

Such a power division and identification system advantageously can be used in a plurality of applications (e.g., theoretically wherever there are cables/connectors that have grounds across the interface and those grounds are tied together at the peripherals). Such a power division and identification system advantageously removes the need for discrete signals for connector/cable assertion detection to validate cable/connectors. Such a power division and identification system advantageously allows for a plurality of components to be powered from a single power source while still achieving cable/connector assertion detection on a per component basis without requiring additional signals.

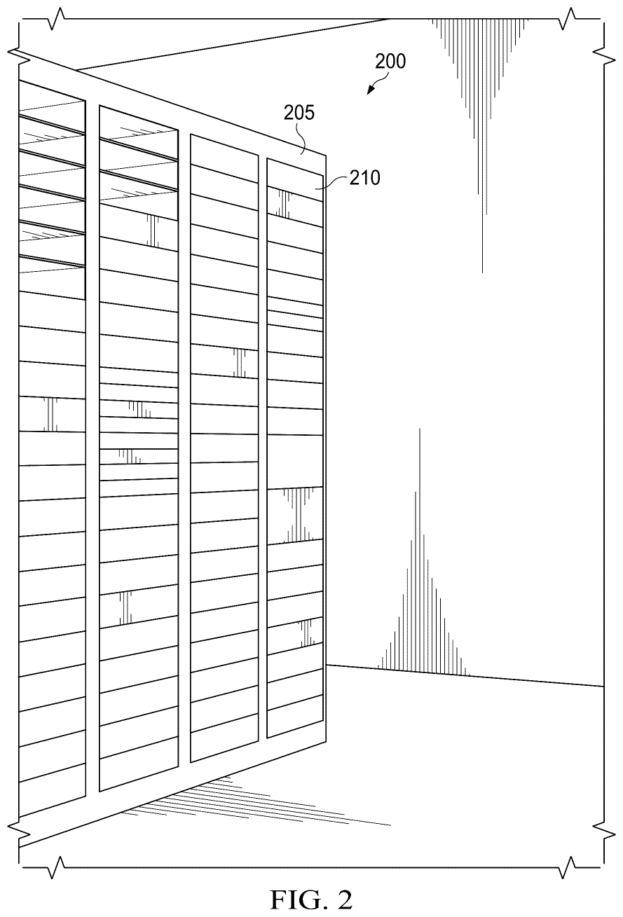

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

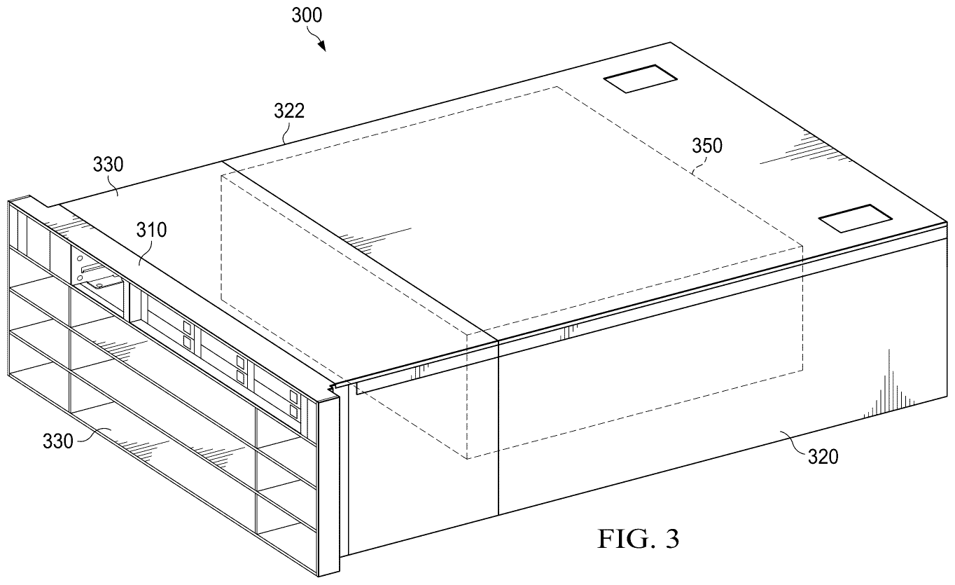

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the server system 300 includes a power division and identification environment 350. In certain embodiments, the power division and identification environment 350 corresponds to power division and identification system 150.

In certain embodiments, the power division and identification environment 350 includes a power system and a plurality of components coupled to the power system. In certain embodiments, the plurality of components are arranged as an array of components. In certain embodiments, the plurality of components includes a plurality of GPUs, a plurality of drives, or a combination thereof. In certain embodiments, the plurality of GPUs, the plurality of drives, or a combination thereof, are designed to support artificial intelligence (AI) workloads.

In certain embodiments, the power division and identification environment 350 includes a power division and identification control circuit, a first power division and identification component circuit, a second power division and identification component circuit, or a combination thereof. In certain embodiments, the power division and identification control circuit is associated with a power system of the server type information handling system. In certain embodiments, the first power division and identification control circuit is associated with a power system of a first component of the information handling system. In certain embodiments, the second power division and identification control circuit is associated with a power system of a second component of the information handling system.

In certain embodiments, the power division and identification circuit, the first power division and identification component circuit and second power division and identification component circuit are coupled via respective monitored and controlled ground signal paths, a common power and sideband signal path, a common passive ground signal path, or a combination thereof. In certain embodiments, the respective monitored and controlled ground signal paths, the common power and sideband signal path, the common passive ground signal path, or a combination thereof, are connected to the power division and identification circuit via a power system power connector. In certain embodiments, the respective monitored and controlled ground signal paths, the common power and sideband signal path, the common passive ground signal path, or a combination thereof, are connected to the first power division and identification component circuit and the second power division and identification component circuit via a first component power system power connector and a second component power system power connector.

In certain embodiments, the first power division and identification component circuit is associated with a first AIC power connector and the second power division and identification component circuit is associated with a second AIC power connector. Accordingly in certain embodiments, a single power connector is split to multiple separate AIC power connectors. Therefore, to power 8x DW cards or 16x SW cards in the same chassis, only 8x source power connectors are needed, assuming the power source connector is adequately gauged to support the periphery loads. In certain embodiments, to enable cable assertion detection between the single power source and the multiple periphery loads (granularly down to a per peripheral basis), grounds are monitored by a power division and identification circuit control device. In certain embodiments, the power division and identification system uses per component monitored/controlled ground signal paths that, when combined with a passive ground on the component side, the cable-to-periphery AIC connection can be identified as ‘asserted’ when the cable is coupled to the respective component by coupling the monitored ground to the passive ground.

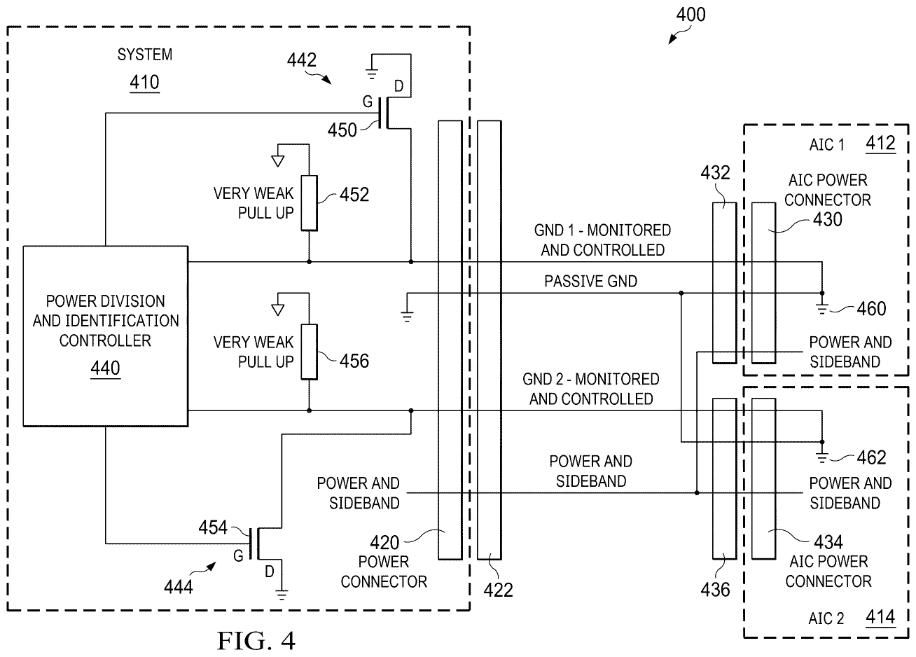

FIG. 4 shows a generalized schematic view of a power division and identification system 400. In certain embodiments, the power division and identification system 400 corresponds to power division and identification system 150.

In certain embodiments, the power division and identification system 400 includes a power division and identification control circuit 410, a first power division and identification component circuit 412, a second power division and identification component circuit 414, or a combination thereof. In certain embodiments, the power division and identification control circuit 410 is associated with a power system of the server type information handling system. In certain embodiments, the first power division and identification control circuit 412 is associated with a power system of a first component of the information handling system. In certain embodiments, the second power division and identification control circuit 414 is associated with a power system of a second component of the information handling system.

In certain embodiments, the power division and identification circuit 410, the first power division and identification component circuit 412 and second power division and identification component circuit 414 are coupled via respective monitored and controlled ground signal paths (GND1, GND2), a common power and sideband signal path (PWR & Sideband), a common passive ground signal path (Passive GND), or a combination thereof. In certain embodiments, the respective monitored and controlled ground signal paths, the common power and sideband signal path, the common passive ground signal path, or a combination thereof, are connected to the power division and identification circuit 410 via a power system power connector 420 and a power system power cable connector 422. In certain embodiments, the first monitored and controlled ground signal path (GND 1), the common power and sideband signal path, the common passive ground signal path, or a combination thereof, are connected to the first power division and identification component circuit 412 via a first component power system power connector 430 and a first component power system power cable connector 432. In certain embodiments, the second monitored and controlled ground signal path (GND 2), the common power and sideband signal path, the common passive ground signal path, or a combination thereof, are connected to the second power division and identification component circuit 414 via a second component power system power connector 434 and a second component power system power cable connector 436.

In certain embodiments, the power division and identification circuit 410 includes a power division and identification controller 440, a first component detection circuit 442, a second component detection circuit 444, or a combination thereof. In certain embodiments, the power division and identification controller 440 can include an application specific integrated circuit (ASIC). In certain embodiments, the power division and identification controller 440 controls performance of a power division and identification operation. As used herein, a power division and identification operation broadly refers a solution which divides a power source connector and a plurality of component power connectors and determines connector assertion between a power source connector and a plurality of different component loads coupled to respective component power connectors. In certain embodiments, the power division and identification operation functions on a per component basis by using ground signal paths.

In certain embodiments, the first component detection circuit 442 includes a switch 450 a pull up circuit 452, or a combination thereof. In certain embodiments, the pull up circuit 452 is coupled to the switch 450 via the first monitored and controlled ground signal path. In certain embodiments, the switch 450 includes a transistor such as a field effect transistor (FET). In certain embodiments, the pull up circuit 452 is configured as a very weak pull up circuit. In certain embodiments, the very weak pull up circuit is configured with a low voltage (e.g., 0.5v (+/−25%)) and a low resistance (e.g., 100 Ohms (+/−25%)) resistor. In certain embodiments, the second component detection circuit 444 includes a switch 454, a pull up circuit 456, or a combination thereof. In certain embodiments, the switch 454 includes a transistor such as a field effect transistor (FET). In certain embodiments, the pull up circuit 456 is configured as a very weak pull up circuit. In certain embodiments, the very weak pull up circuit is configured with a low voltage (e.g., 0.5v (+/−25%)) and a low resistance (e.g., 100 Ohms (+/−25%)) resistor. In certain embodiments, the resistance between drain and source (RDS) of each of the FETs is selected to function with the values of the pull up circuit to turn on when the monitored and controlled ground signal path is coupled to ground at the corresponding power division and identification component circuit. In certain embodiments, one or both of the FETs may be configured as powered FETs to function with the values of the respective pull up circuit to turn on when the monitored and controlled ground signal path is coupled to ground at the corresponding power division and identification component circuit.

In certain embodiments, the first power division and identification component circuit 412 includes a ground 460. In certain embodiments, the first monitored and controlled ground signal path (GND 1) and common passive ground signal path are connected via the ground 460. In certain embodiments, by connecting the first monitored and controlled ground signal path (GND 1) and common passive ground signal path via the ground 460, when the first power division and identification component circuit 412 is connected to the power division and identification circuit 410, the ground pulls the first monitored and controlled ground signal path to ground, thus enabling the power division and identification controller 440 to detect that first power division and identification component circuit 412 is connected to the power division and identification circuit 410.

In certain embodiments, second power division and identification component circuit 414 includes a ground 462. In certain embodiments, the second monitored and controlled ground signal path (GND 2) and common passive ground signal path are connected via the ground 460. In certain embodiments, by connecting the second monitored and controlled ground signal path (GND 2) and common passive ground signal path via the ground 462, when the second power division and identification component circuit 412 is connected to the power division and identification circuit 410, the ground pulls the second monitored and controlled ground signal path to ground, thus enabling the power division and identification controller 440 to detect that second power division and identification component circuit 414 is connected to the power division and identification circuit 410.

In certain embodiments, the first power division and identification component circuit 412 is associated with a first AIC component via a first AIC power connector and the second power division and identification component circuit 414 is associated with a second AIC component via a second AIC power connector. Accordingly in certain embodiments, a single power connector is split to multiple separate AIC power connectors. Therefore, to power 8x double wide (DW) cards or 16x single wide (SW) cards in the same chassis, only 8x source power connectors are needed, assuming the power source connector is adequately gauged to support the periphery loads. In certain embodiments, to enable cable assertion detection between the single power source and the multiple periphery loads (granularly down to a per peripheral basis), grounds are monitored by a power division and identification circuit control device. In certain embodiments, the power division and identification system uses per component monitored/controlled ground signal paths that, when combined with a passive ground on the component side, the cable-to-periphery AIC connection can be identified as ‘asserted’ when the cable is coupled to the respective component by coupling the monitored ground to the passive ground.

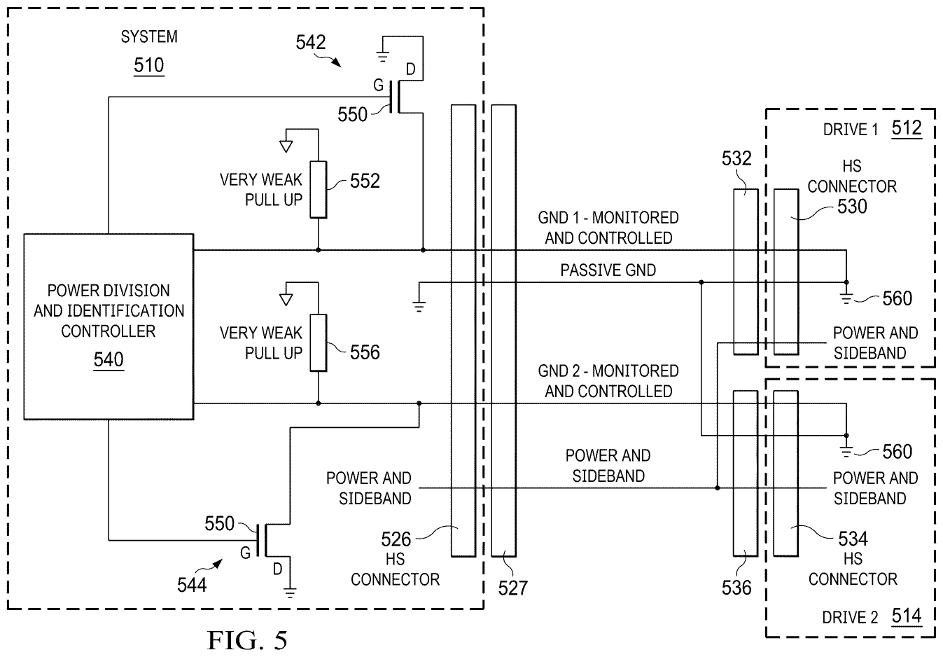

FIG. 5 shows a generalized schematic view of a power division and identification system 500. In certain embodiments, the power division and identification system 500 corresponds to power division and identification system 150.

In certain embodiments, the power division and identification system 500 includes a power division and identification control circuit 510, a first power division and identification component circuit 512, a second power division and identification component circuit 514, or a combination thereof. In certain embodiments, the power division and identification control circuit 510 is associated with a power system of the server type information handling system. In certain embodiments, the first power division and identification control circuit 512 is associated with a power system of a first component of the information handling system. In certain embodiments, the second power division and identification control circuit 514 is associated with a power system of a second component of the information handling system.

In certain embodiments, the power division and identification circuit 510, the first power division and identification component circuit 512 and second power division and identification component circuit 514 are coupled via respective monitored and controlled ground signal paths (GND1, GND2), a common power and sideband signal path (PWR & Sideband), a common passive ground signal path (Passive GND), or a combination thereof. In certain embodiments, the respective monitored and controlled ground signal paths, the common power and sideband signal path, the common passive ground signal path, or a combination thereof, are connected to the power division and identification circuit 510 via a power system power connector 520 and a power system power cable connector 522. In certain embodiments, the first monitored and controlled ground signal path (GND 1), the common power and sideband signal path, the common passive ground signal path, or a combination thereof, are connected to the first power division and identification component circuit 512 via a first component power system power connector 530 and a first component power system power cable connector 532. In certain embodiments, the second monitored and controlled ground signal path (GND 2), the common power and sideband signal path, the common passive ground signal path, or a combination thereof, are connected to the second power division and identification component circuit 514 via a second component power system power connector 534 and a second component power system power cable connector 536.

In certain embodiments, the power division and identification circuit 510 includes a power division and identification controller 540, a first component detection circuit 542, a second component detection circuit 544, or a combination thereof. In certain embodiments, the power division and identification controller 540 can include an application specific integrated circuit (ASIC). In certain embodiments, the power division and identification controller 440 controls performance of a power division and identification operation.

In certain embodiments, the first component detection circuit 542 includes a switch 550 a pull up circuit 552, or a combination thereof. In certain embodiments, the pull up circuit 552 is coupled to the switch 550 via the second monitored and controlled ground signal path. In certain embodiments, the switch 550 includes a transistor such as a field effect transistor (FET). In certain embodiments, the pull up circuit 552 is configured as a very weak pull up circuit. In certain embodiments, the very weak pull up circuit is configured with a low voltage (e.g., 0.5v (+/−25%)) and a low resistance (e.g., 100 Ohms (+/−25%)) resistor. In certain embodiments, the second component detection circuit 544 includes a switch 554, a pull up circuit 556, or a combination thereof. In certain embodiments, the switch 554 includes a transistor such as a field effect transistor (FET). In certain embodiments, the pull up circuit 556 is configured as a very weak pull up circuit. In certain embodiments, the very weak pull up circuit is configured with a low voltage (e.g., 0.5v (+/−25%)) and a low resistance (e.g., 100 Ohms (+/−25%)) resistor. In certain embodiments, the resistance between drain and source (RDS) of each of the FETs is selected to function with the values of the pull up circuit to turn on when the monitored and controlled ground signal path is coupled to ground at the corresponding power division and identification component circuit. In certain embodiments, one or both of the FETs may be configured as powered FETs to function with the values of the respective pull up circuit to turn on when the monitored and controlled ground signal path is coupled to ground at the corresponding power division and identification component circuit.

In certain embodiments, the first power division and identification component circuit 512 includes a ground 560. In certain embodiments, the first monitored and controlled ground signal path (GND 1) and common passive ground signal path are connected via the ground 560. In certain embodiments, by connecting the first monitored and controlled ground signal path (GND 1) and common passive ground signal path via the ground 560, when the first power division and identification component circuit 512 is connected to the power division and identification circuit 510, the ground pulls the first monitored and controlled ground signal path to ground, thus enabling the power division and identification controller 540 to detect that first power division and identification component circuit 512 is connected to the power division and identification circuit 510.

In certain embodiments, second power division and identification component circuit 514 includes a ground 562. In certain embodiments, the second monitored and controlled ground signal path (GND 2) and common passive ground signal path are connected via the ground 560. In certain embodiments, by connecting the second monitored and controlled ground signal path (GND 2) and common passive ground signal path via the ground 562, when the second power division and identification component circuit 512 is connected to the power division and identification circuit 510, the ground pulls the second monitored and controlled ground signal path to ground, thus enabling the power division and identification controller 540 to detect that second power division and identification component circuit 514 is connected to the power division and identification circuit 510.

In certain embodiments, the first power division and identification component circuit 512 is associated with a first drive component via a first drive power connector and the second power division and identification component circuit 514 is associated with a second drive component via a second drive power connector. Accordingly in certain embodiments, a single power connector is split to multiple separate drive power connectors. Therefore, to power 8x double wide (DW) cards or 16x single wide (SW) cards in the same chassis, only 8x source power connectors are needed, assuming the power source connector is adequately gauged to support the periphery loads. In certain embodiments, to enable cable assertion detection between the single power source and the multiple periphery loads (granularly down to a per peripheral basis), grounds are monitored by a power division and identification circuit control device. In certain embodiments, the power division and identification system uses per component monitored/controlled ground signal paths that, when combined with a passive ground on the component side, the cable-to-periphery AIC connection can be identified as ‘asserted’ when the cable is coupled to the respective component by coupling the monitored ground to the passive ground.

Other embodiments are within the following claims. For example, a single power division and identification circuit could be associated with more than two component circuits by adding additional component detection circuit along with additional associated signal paths.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A power division and identification system for use with an information handling system, comprising:
a power division and identification control circuit;
a first power division and identification component circuit, the power division and identification circuit and the first power division and identification component circuit being coupled via a first monitored and controlled ground signal path and a common passive ground signal path; and,
a second power division and identification component circuit, the power division and identification circuit, the power division and identification circuit and the second power division and identification component circuit being coupled via a second monitored and controlled ground signal path and the common passive ground signal path.

2. The power division and identification system of claim 1, wherein:
the power division and identification circuit and the first power division and identification component circuit are coupled via a common power and sideband signal path; and,
the power division and identification circuit and the second power division and identification component circuit are coupled via the common power and sideband signal path.

3. The power division and identification system of claim 1, wherein:
the first monitored and controlled ground signal path and the common passive ground signal path are coupled within the first power division and identification component circuit via ground; and,
the second monitored and controlled ground signal path and the common passive ground signal path are coupled within the second power division and identification component circuit via ground.

4. The power division and identification system of claim 1, wherein:
the power division and identification control circuit includes a power division and identification device, a first component detection circuit coupled to the first power division and identification component circuit, and a second component detection circuit coupled to the second power division and identification component circuit.

5. The power division and identification system of claim 4, wherein:
the first component detection circuit includes a switch and a pull up circuit coupled to the switch via the first monitored and controlled ground signal path.

6. The power division and identification system of claim 5, wherein:
the switch includes a transistor; and,
the pull up circuit is configured as a very weak pull up circuit.

7. A power division and identification environment for an information handling system comprising:
a plurality of components; and,
a power system providing power to the plurality of components, the power system including a power division and identification system, the power division and identification system comprising
a power division and identification control circuit;
a first power division and identification component circuit, the power division and identification circuit and the first power division and identification component circuit being coupled via a first monitored and controlled ground signal path and a common passive ground signal path; and,
a second power division and identification component circuit, the power division and identification circuit, the power division and identification circuit and the second power division and identification component circuit being coupled via a second monitored and controlled ground signal path and the common passive ground signal path.

8. The power division and identification environment of claim 7, wherein:
the power division and identification circuit and the first power division and identification component circuit are coupled via a common power and sideband signal path; and,
the power division and identification circuit and the second power division and identification component circuit are coupled via the common power and sideband signal path.

9. The power division and identification environment of claim 7, wherein:
the first monitored and controlled ground signal path and the common passive ground signal path are coupled within the first power division and identification component circuit via ground; and,
the second monitored and controlled ground signal path and the common passive ground signal path are coupled within the second power division and identification component circuit via ground.

10. The power division and identification environment of claim 7, wherein:
the power division and identification control circuit includes a power division and identification device, a first component detection circuit coupled to the first power division and identification component circuit, and a second component detection circuit coupled to the second power division and identification component circuit.

11. The power division and identification environment of claim 10, wherein:
the first component detection circuit includes a switch and a pull up circuit coupled to the switch via the first monitored and controlled ground signal path.

12. The power division and identification environment of claim 11, wherein:
the switch includes a transistor; and,
the pull up circuit is configured as a very weak pull up circuit.

13. A system comprising:
a chassis;
a plurality of components contained within the chassis; and,
a power system providing power to the plurality of components, the power system including a power division and identification system, the power division and identification system comprising
a power division and identification control circuit;
a first power division and identification component circuit, the power division and identification circuit and the first power division and identification component circuit being coupled via a first monitored and controlled ground signal path and a common passive ground signal path; and,
a second power division and identification component circuit, the power division and identification circuit, the power division and identification circuit and the second power division and identification component circuit being coupled via a second monitored and controlled ground signal path and the common passive ground signal path.

14. The system of claim 13, wherein:
the power division and identification circuit and the first power division and identification component circuit are coupled via a common power and sideband signal path; and,
the power division and identification circuit and the second power division and identification component circuit are coupled via the common power and sideband signal path.

15. The system of claim 13, wherein:
the first monitored and controlled ground signal path and the common passive ground signal path are coupled within the first power division and identification component circuit via ground; and,
the second monitored and controlled ground signal path and the common passive ground signal path are coupled within the second power division and identification component circuit via ground.

16. The system of claim 13, wherein:
the power division and identification control circuit includes a power division and identification device, a first component detection circuit coupled to the first power division and identification component circuit, and a second component detection circuit coupled to the second power division and identification component circuit.

17. The system of claim 16, wherein:
the first component detection circuit includes a switch and a pull up circuit coupled to the switch via the first monitored and controlled ground signal path.

18. The system of claim 17, wherein:
the switch includes a transistor; and,
the pull up circuit is configured as a very weak pull up circuit.
